(19) United States
(12) Patent Application Publication
(10) Pub. No.: US 2014/0151891 A1
(43) Pub. Date: Jun. 5, 2014

(54) SEMICONDUCTOR PACKAGE

(71) Applicant: SHINKO ELECTRIC INDUSTRIES CO., LTD., Nagano-shi (JP)

(72) Inventors: Akihito TAKANO, Nagano-shi (JP); Mitsuhiro AIZAWA, Nagano-shi (JP); Koji HARA, Nagano-shi (JP)

(73) Assignee: SHINKO ELECTRIC INDUSTRIES CO., LTD., Nagano-shi (JP)

(21) Appl. No.: 14/087,461

(22) Filed: Nov. 22, 2013

(30) Foreign Application Priority Data
Dec. 5, 2012 (JP) 2012-266524

(51) Int. Cl. H01L 23/34

(52) U.S. Cl. CPC H01L 23/34
USPC 257/773

(57) ABSTRACT

A semiconductor package includes: a first wiring substrate; a first spacer on the first wiring substrate, wherein the first spacer has a rectangular shape; a second spacer on the first wiring substrate to be separated from the first spacer, wherein the second spacer has a rectangular shape; a second wiring substrate on the first spacer and the second spacer and having a first surface and a second surface which is opposite to the first surface, wherein the second wiring substrate has opposed sides; a first semiconductor chip on the first surface of the second wiring substrate; and a second semiconductor chip on the second surface of the second wiring substrate to be disposed between the first spacer and the second spacer. The opposed long sides of the first and second spacers are substantially parallel with the opposed sides of the second wiring substrate.

This application claims priority from Japanese Patent Application No. 2012-266524, filed on Dec. 5, 2012, the entire contents of which are herein incorporated by reference.

### BACKGROUND OF THE INVENTION

1. Technical Field

The present disclosure relates to a semiconductor package.

2. Description of the Related Art

A semiconductor package is configured to contain a plurality of semiconductor devices (or semiconductor chips) and other electronic components (see JP-A-11-345932 and JP-A-2003-60153, for example). An example of the semiconductor package is illustrated in FIG. 19A. In this semiconductor package, a silicon interposer 102 is mounted on a package substrate 101, and a plurality of (four in the drawing) semiconductor chips 103 are mounted on the silicon interposer 102.

Incidentally, in order to increase the number of the semiconductor chips contained in one semiconductor package without changing the size of the silicon interposer, it may be an attractive way to mount the semiconductor chips on the lower surface of the silicon interposer. However, in the semiconductor package illustrated in FIG. 19A, a distance from the silicon interposer 102 to the package substrate 101 is too narrow to mount the semiconductor chips on the lower surface of the silicon interposer 102. Alternatively, it may be another attractive way to use a package substrate 104 having a concave portion 104a for accommodating a semiconductor chip 103, as illustrated in FIG. 19B. In addition, it may be thought to enlarge bumps 105 that connect the silicon interposer 102 and the package substrate 01, in order to ensure a space that enables mounting the semiconductor chip on the lower surface of the interposer 102, as illustrated in FIG. 19C.

However, in the example illustrated in FIG. 19B, the package substrate tends to be warped because of the concave portion 104a, which may lead to the reduced production yield and/or the reduced reliability of the semiconductor package. In addition, in the example illustrated in FIG. 19C, the number of terminals (or bumps) needs to be reduced, which may make it difficult to ensure the number of terminals necessary to connect the semiconductor chips 103. On the other hand, when the necessary number of terminals is formed, the sizes of the bumps 105 are restrained, which may make the distance from the silicon interposer 102 to the package substrate 101 too narrow to mount the semiconductor chip 103 therein.

### SUMMARY OF THE INVENTION

According to one or more illustrative aspects of the present invention, there is provided a semiconductor package. The semiconductor package comprises: a first wiring substrate; a first spacer on the first wiring substrate, wherein the first spacer has a rectangular shape having opposed short sides and opposed long sides; a second spacer on the first wiring substrate to be separated from the first spacer, wherein the second spacer has a rectangular shape having opposed short sides and opposed long sides; a second wiring substrate on the first spacer and the second spacer and comprising a first surface and a second surface which is opposite to the first surface and faces the first and second spacers, wherein the second wiring substrate has opposed sides; a first semiconductor chip on the first surface of the second wiring substrate; and a second semiconductor chip on the second surface of the second wiring substrate to be disposed between the first spacer and the second spacer. The opposed long sides of the first spacer and the opposed long sides of the second spacer are substantially parallel with the opposed sides of the second wiring substrate.

According to one aspect of the present invention, high density packaging of semiconductor chips can be,realized.

### BRIEF DESCRIPTION OF THE DRAWINGS

FIG. 1 is a schematic plan view of a semiconductor package according to an embodiment of the present invention;

FIG. 2 is a schematic cross-sectional view of the semiconductor package;

FIG. 3 is a schematic perspective view of an interposer and a semiconductor element;

FIG. 4A is a schematic plan view of an interposer of a reference example;

FIG. 4B is a schematic perspective view of the interposer of the reference example;

FIGS. 5A through 5C are schematic cross-sectional view illustrating a method of producing the semiconductor package according to the embodiment of the present invention;

FIG. 6 is a schematic plan view of the semiconductor package;

FIG. 7 is a schematic cross-sectional view of the semiconductor package;

FIGS. 8A through 8C are schematic cross-sectional views illustrating the method of producing the semiconductor package;

FIG. 9 is a schematic perspective view of the semiconductor package;

FIG. 10 is a schematic cross-sectional view of the semiconductor package;

FIG. 11 is an exploded perspective view of the semiconductor package;

FIG. 12 illustrates a back surface of a heat radiating cover;

FIG. 13 is a schematic plan view of another semiconductor package;

FIG. 14 is a schematic plan view of the semiconductor package;

FIGS. 15A and 15B are schematic cross-sectional views illustrating another method of producing a semiconductor package;

FIGS. 16A and 16B are schematic cross-sectional views illustrating another method of producing a semiconductor package;

FIGS. 17A and 17B are schematic cross-sectional views illustrating another method of producing a semiconductor package;

FIGS. 18A through 18C are schematic cross-sectional views illustrating another method of producing a semiconductor package; and

FIGS. 19A through 19C are schematic cross-sectional views illustrating related-art semiconductor packages.

### DETAILED DESCRIPTION

In the following, exemplary embodiments according to the present invention will be now described with reference to the accompanying drawings.

The accompanying drawings may illustrate features of the embodiments in an enlarged form for the sake of illustration, in order to make the features easily understood. Thus, there is no intention to indicate scale or relative proportions among members or components. In addition, hatching of parts of the members or components will be omitted in some cross-sectional views, in order to make their cross-sectional structures easily understood.

### First Embodiment

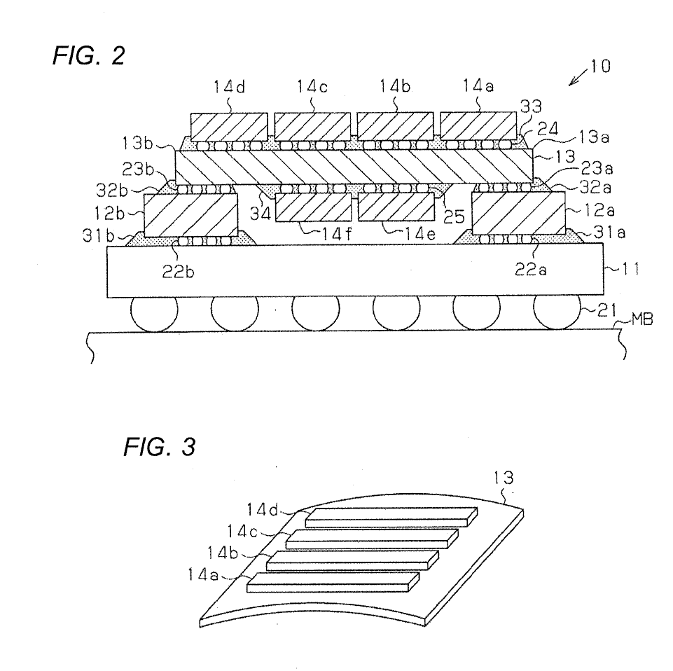

As shown in FIG. 2, a semiconductor package 10 is mounted on one main surface (an upper surface in the drawing) of a mounting board (for example, a mother board) MB.

The semiconductor package 10 includes a package substrate 10, two spacers 12a, 12b, an intermediate substrate 13, a plurality of (six in FIG. 2) semiconductor chips 14a through 14f. The semiconductor chips 14a through 14f may be referred to simply as semiconductor chips 14 herein, when there is no need for specifying each of the semiconductor chips 14a through 14f.

The package substrate 11 is connected to the mounting board MB through a plurality of bumps 21 formed on a lower surface (a second main surface) of the package substrate 11. The package substrate 11 is one example of a first wiring substrate. The bumps 21 are arranged, for example, in a matrix in planar view. The bumps 21 may be, for example, solder bumps.

The package substrate 11 has the shape of, for example, a rectangle in planar view. The package substrate 11 is formed of, for example, an organic base material, which may contain a fiber material such as glass. The package substrate 11 allows bumps 22a, 22b for electrical connection, which are formed on an upper surface thereof, and the bumps 21 for mounting, which are formed on the lower surface thereof, to be electrically connected to each other. Namely, a wiring layer may be formed within the package substrate 11, although not essential. In the package substrate 11 including the wiring layer, a plurality of the wiring layers are formed together with insulating layers in-between. Each of the wiring layers and vias formed within the insulating layers make it possible to electrically connect the bumps 21 and the bumps 22a, 22b. As the package substrate 11, a build-up substrate with a core substrate, a coreless substrate having no core substrate, or the like may be used.

As illustrated in FIG. 2, the two spacers 12a, 12b are mounted on the upper surface (a first main surface) of the package substrate 11. The package substrate 11 and the spacer 12a are electrically connected to each other through the bumps 22a. Similarly, the package substrate 11 and the spacer 12b are electrically connected to each other through the bumps 22b. The bumps 22a, 22b may be, for example, solder bumps.

End portions of the intermediate substrate 13 are arranged substantially on the spacerss 12a, 12b. The spacer 12a and the intermediate substrate 13 are electrically connected to each other through a plurality of bumps 23a. Similarly, the spacer 12b and the intermediate substrate 13 are electrically connected to each other through a plurality of bumps 23b. The bumps 23a, 23b may be, for example, solder bumps. The thickness of the spacers 12a, 12b is set depending on the semiconductor chip 14e, 14f. The thickness of the semiconductor chips 14e, 14f may be, for example, 50 to 700 μm. The thickness of the spacers 12a, 12b may be, for example, 100 to 800 μm.

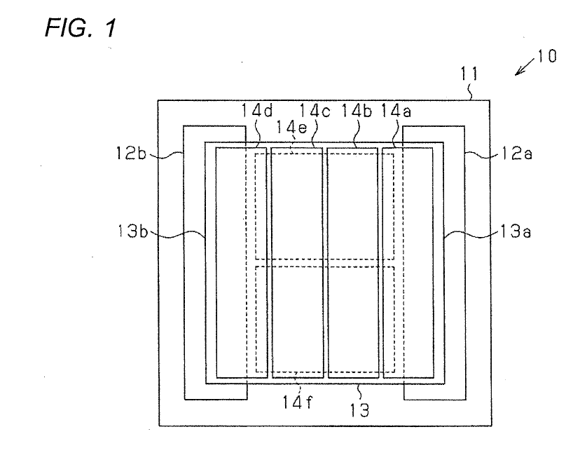

Referring to FIG. 1, each of the spacers 12a, 12b is formed to have the shape of a rectangle in planar view. Each of the spacers 12a, 12b extends along a pair of opposing sides 13a, 13b of the intermediate substrate 13. The length of the spacers 12a, 12b is set to be longer than the sides 13a, 13b of the intermediate substrate 13. In addition, the position and width of the spacers 12a, 12b are determined in such a manner that each of the spacers 12a, 12b extends outwardly from the intermediate substrate 13 in a width direction (a horizontal direction in FIG. 1). In other words, the side 13a of the intermediate substrate 13 is positioned within the spacer 12a in planar view; and the side 13b of the intermediate substrate 13 is positioned within the spacer 12b in planar view.

Incidentally, referring to FIG. 1, the semiconductor chips 14e, 14f are mounted on the lower surface of the intermediate substrate 13, and specifically arranged in a direction along which the spacers 12a, 12b extend, which is different from those illustrated in FIG. 2. It should be noted that the semiconductor chips 14e, 14f are illustrated in such a different manner in FIG. 2, in order to illustrate two semiconductor chips are mounted on the lower surface of the intermediate substrate 13.

The spacers 12a, 12b may be formed of, for example, silicon (Si). The spacers 12a, 12b include through electrodes (not illustrated) that are insulated from the spacers 12a, 12b. The through electrodes electrically connect the bumps 23a, 23b that are provided on the first main surfaces (the upper surfaces in FIG. 2) of the spacers 12a, 12b, respectively, with the bumps 22a, 22b that are provided on the second main surfaces (lower surfaces in FIG. 2) of the spacers 12a, 12b, respectively. The spacers 12a, 12b may include a wiring layer electrically connected to the through electrodes.

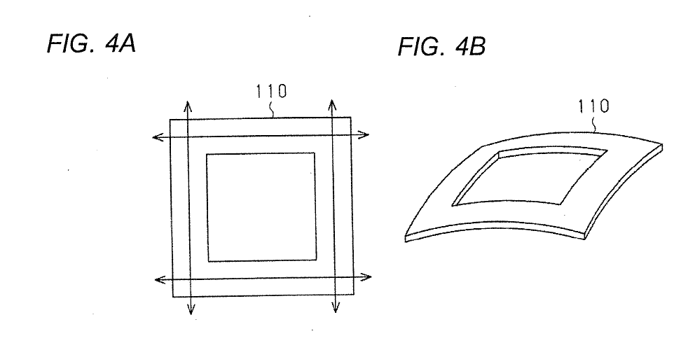

On the first main surface (the upper surface in FIG. 2) of the intermediate substrate 13, a plurality of (four in FIG. 4) semiconductor chips 14a through 14d are mounted through bumps 24. On the second main surface (the lower surface) of the intermediate substrate 13, the plurality of (two in FIG. 4) semiconductor chips 14e, 14f are mounted through bumps 25 in a center in a right-and-left direction in FIG. 2. The bumps 24, 25 may be, for example, solder bumps. The intermediate substrate 13 is one example of a second wiring substrate.

The intermediate substrate 13 may be formed of, for example, silicon. The intermediate substrate 13 includes a wiring (not illustrated), and a through electrode (not illustrated) that is insulated from the intermediate substrate 13 and penetrates through the intermediate substrate 13. The through electrode and the wiring electrically connect the bumps 24, 25, which are provided between the intermediate substrate 13 and the semiconductor chips 14a through 14f, with the bumps 23a, 23b, which are provided between the intermediate substrate 13 and the spacer 12a, 12b, in an arbitrary manner (or in accordance with a circuit design, for example).

Underfill resin portions 31a, 31b are provided between the package substrate 11 and the spacers 12a, 12b, respectively. Similarly, underfill resin portions 32a, 32b are provided between the spacers 12a, 12b and the intermediate substrate 13, respectively. In addition, an underfill resin portion 33 is provided between the intermediate substrate 13 and the semiconductor chips 14a through 14d. Moreover, an underfill portion 34 is provided between the intermediate substrate 13 and the semiconductor chips 14e, 14f.

As illustrated in FIG. 2, the spacers 12a, 12b are connected on the upper surface of the package substrate 11. The package substrate 11 extends outwardly from end portions of the spacers 12a, 12b. Therefore, the underfill resin portion 31a (or 31b) formed between the package substrate 11 and the spacer 12a (or 12b) has in a periphery a fillet that spreads so as to be smoothly slanted from a lower side portion of the spacer 12a (or 12b) toward the upper surface of the package substrate 11.

Similarly, the spacers 12a, 12b extend outwardly from the end portions of the intermediate substrate 13. Therefore, the underfill resin portion 32a (or 32b) formed between the spacer 12a (or 12b) and the intermediated substrate 13 has in a periphery thereof a fillet that spreads so as to be smoothly slanted from the intermediate substrate 13 toward the spacer 12a (or 12b). In addition, the semiconductor chips 14a through 14d are arranged on the upper surface of the intermediate substrate 13, or specifically arranged inwardly from the end portions of the intermediate substrate 13. Therefore, the underfill resin portion 33 formed between the intermediate substrate 13 and the semiconductor chips 14a through 14d has in a periphery thereof a fillet that spreads so as to be smoothly slanted from lower side portions of the semiconductor chips 14a through 14d toward the upper surface of the intermediate substrate 13. Moreover, the semiconductor chips 14e, 14f are arranged on the lower surface of the intermediate substrate 13 in a center region. Therefore, the underfill resin portion 34 formed between the intermediate substrate 13 and the semiconductor chips 14e, 14f has in a periphery thereof a fillet that spreads so as to be smoothly slanted from upper side portions of the semiconductor chips 14e, 14f toward the lower surface of the intermediate substrate 13.

Each of the underfill resin portions 31a through 34 enhances the connection strength between the corresponding two substrates, and reduces troubles in the wiring or the like. For example, the.underfill resin portion 31a (or 31b) enhances the connection strength between the package substrate 11 and the spacer 12a (or 12b). In addition, the underfill resin portions 31a (or 31b) suppresses corrosion of connection pads (not illustrated) formed on the package substrate 11 and the spacer 12a (or 12b), occurrence of electromigration, the reduced reliability of wiring, or the like. As a material of the underfill resin portions 31a, 31b, an insulating resin such as an epoxy-based resin and a polyimide-based resin, or a resin material obtained by mixing a filler such as silica and alumina to the insulating resin.

In this embodiment, the underfill resin portions 31a through 34 are formed of the same material. However, the underfill resin portions 31a through 34 may be formed of different materials in other embodiments. Alternatively, only one of the underfill resin portions 31a through 34 may be formed of a different material in other embodiments.

Next, effects obtained from the semiconductor package 10 will be explained. As illustrated in FIG. 2, the spacers 12a, 12b allow the intermediate substrate 13 to be positioned at a predetermined distance from the package substrate 11, which makes it possible to make a space that can accommodate the semiconductor chips 14e, 14f between the upper surface of the package substrate 11 and the lower surface of the intermediate substrate 13. With this, the semiconductor chips 14e, 14f can be mounted on the lower surface of the intermediate substrate 13. Therefore, the mounting density of semiconductor chips in the intermediate substrate 13 can be increased, compared with a case where the semiconductor chips are mounted only on the upper surface of the intermediate substrate 13.

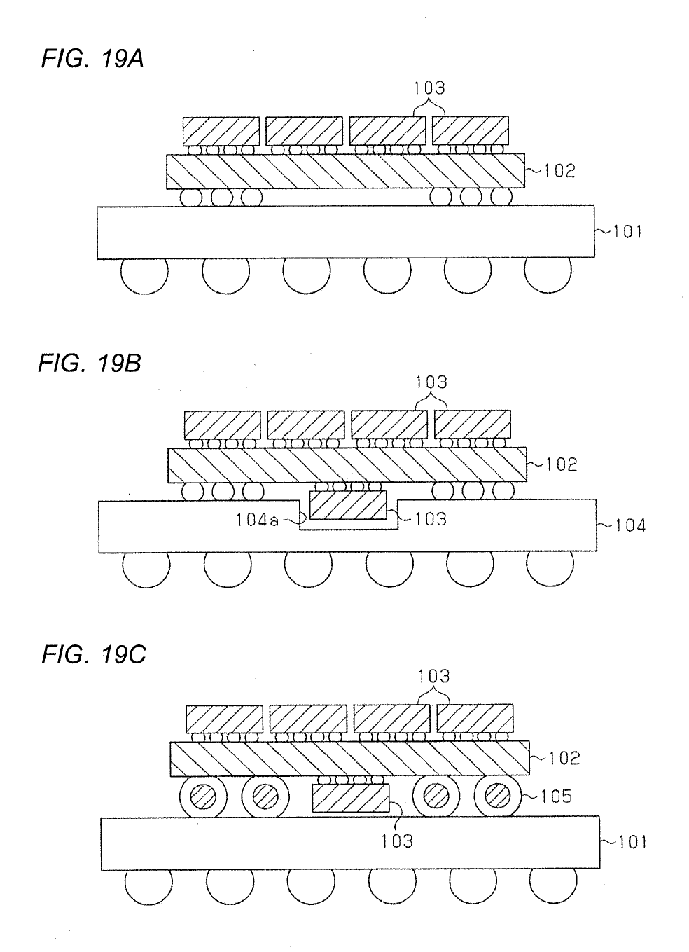

The package substrate 11 and the spacer 12a (or 12b) is connected to each other through the bumps 22a (or 22b). The bumps 22a (or 22b) are formed to have sufficient sizes that make it possible to connect the package substrate 11 and the spacer 12a (or 12b). Similarly, the spacer 12a (or 12b) and the intermediate substrate 13 are connected to each other through the bumps 23a (or 23b) that have sufficient sizes that make it possible to surely connect the spacers 12a, 12b and the intermediate substrate 13. Therefore, there is no need to form the concave portion 104a illustrated in the related art example of FIG. 19B in the package substrate 11, and thus it becomes possible to suppress the reduced strength of the package substrate 11, the reduced production yield of the semiconductor package 10, the reduced reliability, and the like. In addition, the large bumps 105 illustrated in the related art example of FIG. 19B are not necessary in the semiconductor package 10. Therefore, a pitch of the bumps 22a through 23b can be made smaller, which makes it possible to cope with an increased number of pins.

Incidentally, the package substrate 11 is an organic substrate in this embodiment, whereas the intermediate substrate 13 and the two spacers 12a, 12b are silicon substrates. Therefore, a coefficient of thermal expansion (CTE) of the package substrate 11, which is the organic substrate, is different from CTEs of the spacers 12a, 12b. Due to the difference of the CTEs, the package substrate 11 and the spacer 12a, 12b can be warped.

Referring again to FIG. 1, the package substrate 11 and the intermediate substrate 13 are connected to each other by the two spacers 12a, 12b that extend along the side of the intermediate substrate 13. Therefore, the package substrate 11 and the spacer 12a, 12b can be warped in a direction along which the spacers 12a, 12b extend (or a longitudinal direction of the spacer 12a (or 12b)).

FIG. 4A illustrates a spacer 110 of a comparative example. The spacer 110 has the shape of a square frame. In a case of this spacer 110, the spacer 110 and a package substrate on which the spacer 110 is connected through bumps may be warped in directions indicated by the arrows in FIG. 4A. Namely, the spacer 110 and the package substrate may be warped in two directions perpendicular to each other (or an upward-and-downward direction and a left-to-right direction in FIG. 4A), as illustrated in FIG. 4B.

In contrast, in this embodiment, the package substrate 11 and the spacers 12a, 12b can be warped along the direction in which the spacers 12a, 12b extend, namely in an upward-and-downward direction in FIG. 1. In such a manner, the spacers 12a, 12b can reduce warpage of the package substrate 11, compared with the spacer 110 having the frame shape.

In addition, as illustrated in FIG. 1, each of the semiconductor chips 14a through 14d mounted on the upper surface of the intermediate substrate 13 has the shape of a rectangle that extends along the same direction in which the spacers 12a, 12b extend. As described above, the package substrate 11, the spacers 12a, 12b and the intermediate substrate 13 are warped due to differences of coefficients of thermal expansion. However, the warpage of the intermediate substrate 13 can be further reduced. This is because the semiconductor chips 14a through 14d are arranged in the direction along which the warpage of the intermediate substrate 13 is caused, as illustrate in FIG. 3, thereby to enhance stiffness of the intermediate substrate 13.

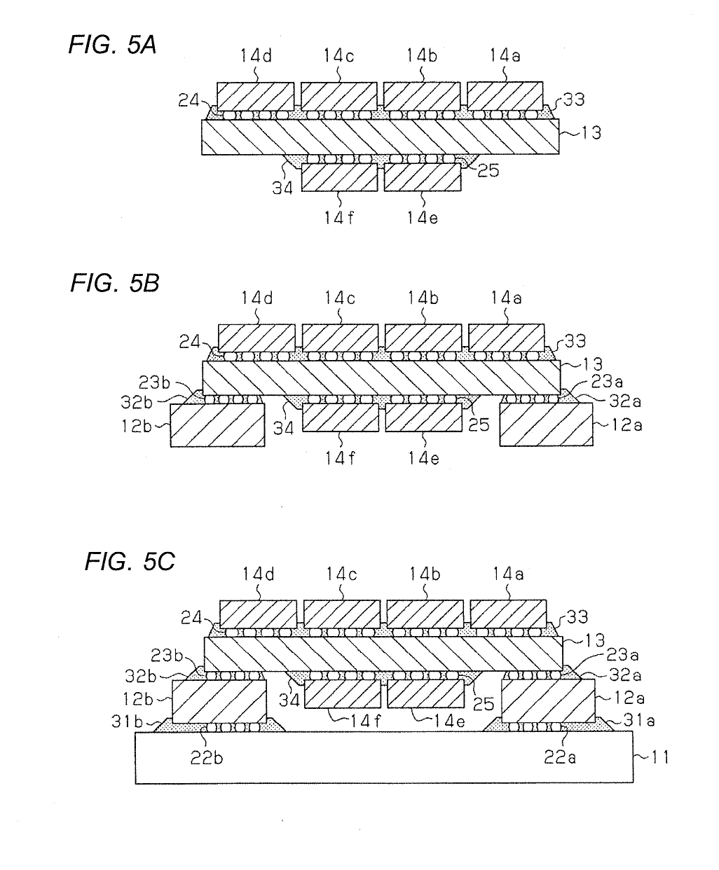

Next, a method of producing the semiconductor package 10 will be explained. Referring to FIG. 5′, the semiconductor chips 14a through 14d are mounted on the upper surface of the intermediate substrate 13; and the semiconductor chips 14e, 14f are mounted on the lower surface of the intermediate substrate 13. Specifically, the semiconductor chips 14a through 14f are adhered on the corresponding surfaces of the intermediate substrate 13, for example, by an adhesive agent or the like, and then connected to the intermediate substrate 13 through the corresponding bumps 24, 25, for example, by performing a re-flow treatment at a temperature of, for example, 250° C. to 270° C. Then, the underfill resin portion 33 is formed between the intermediate substrate 13 and the semiconductor chips 14a through 14d; and the underfill resin portion 34 is formed between the intermediate substrate 13 and the semiconductor chips 14e, 14f. The underfill resin portions 33, 34 are cured at a temperature of, for example, 150° C. to 200° C. by a heating treatment.

Next, referring to FIG. 5B, the spacers 12a, 12b are mounted on lower end portions of the intermediate substrate 13. Then the underfill resin portion 32a (or 32b) is formed between the intermediate substrate 13 and the spacer 12a (or 12b).

Next, referring to FIG. 5C, the spacers 12a, 12b are mounted on the upper surface of the package substrate 11. Then, the, underfill resin portion 31a (or 31b) is formed between the package substrate 11 and the spacer 12a (or 12b).

In processes illustrated in FIGS. 5A and 5B, the semiconductor chips 14a through 14f, the intermediate substrate 13, and the spacers 12a, 12b are formed of a material using silicon as a base material. Therefore, warpage is scarcely caused by the heating treatment. In a process illustrated in FIG. 5C, the spacers 12a, 12b of silicon substrates are mounted on the package substrate 11 of the organic substrate. At this time, because the coefficient of thermal expansion of the package substrate 11 and the coefficient of thermal expansion of the spacers 12a, 12b or the like are different, warpage is caused by a heating treatment. Regarding such warpage, the two spacers 12a, 12b define a warpage direction along which the package substrate 11 or the like is warped.

In addition, the underfill resin portion 32a (or 32b) formed between the intermediate substrate 13 and the spacer 12a (or 12b) has the fillet that smoothly spreads from intermediate substrate 13 toward the upper surface of the spacer 12a (or 12b). The underfill resin portions 12a, 12b enhance the stiffness of the spacers 12a, 12b and the intermediate substrate 13, thereby reducing the warpage.

Moreover, each of the semiconductor chips 14a through 14d mounted on the upper surface of the intermediate substrate 13 has the shape of a rectangle that extends along the warpage direction. Furthermore, the underfill resin portion 33 formed between the intermediate substrate 13 and the semiconductor chips 14a through 14d enhance the stiffness of the, intermediate substrate 13, thereby reducing the warpage of the semiconductor package 10.

By connecting the spacers 12a, 12b to the package substrate 11 as illustrated in FIG. 1, the warpage direction is defined as illustrated in FIG. 3. However, because the bumps 22a, 22b, 23a, 23b are given a concentrated stress originated from the warpage, it is advantageous to increase a contact area of the spacers 12a, 12b and the intermediate substrate 13 and a contact area of the spacer 12a, 12b and the package substrate 11, and to form the underfill resin portions 31a, 31b, 32a, 32b for ensuring the connection strength. Specifically, because contact surfaces (upper surfaces) of the spacers 12a, 12b are arranged so that the spacers 12a, 12b extend outwardly from the intermediate substrate 13 in order to make it easy to inject an underfill resin, the connection strength tends to be reduced, compared with the connection strength between the spacers I 2a, 12b and the package substrate 11, where substantially entire bottom surfaces of the spacers 12a, 12b contact the package substrate 11 through the underfill resin portions 31a, 31b, respectively. As a countermeasure to such tendency, it is advantageous to provide the underfill resin portions 32a, 32b between the intermediate substrate 13 and the spacers 12a, 12b, respectively, in order to suppress the reduction of the connection strength. In addition, in a case of the spacers 12a, 12b formed of silicon, because stress originated from the warpage is concentrated onto a portion between the package substrate 11 and the spacers 12a, 12b, it is advantageous to provide the underfill resin portions 31a, 31b between the package substrate 11 and the spacers 12a, 12b, respectively.

As described above, the advantages obtained by this embodiment are substantially summarized as follows.

(1-1) The spacers 12a, 12b allow the intermediate substrate 13 to be positioned at a predetermined distance from the package substrate 11. With this, a sufficient space for accommodating the semiconductor chips 14e, 14f can be formed between the upper surface of the package substrate 11 and the lower surface of the intermediate substrate 13, which makes it possible to mount the semiconductor chips 14e, 14f on the lower surface of the intermediate substrate 13. Therefore, a mounting density of semiconductor chips mounted on the intermediate substrate 13 can be increased in this embodiment, compared with a case where the semiconductor chips are mounted only on the upper surface of the intermediate substrate 13.

(1-2) The package substrate 11 and the spacer 12a (or 12b) are connected to each other through the bumps 22a (or 22b). The bumps 22a, 22b are formed to have a sufficient size capable of connecting the package substrate 11 and the spacers 12a, 12b. Similarly, the spacer 12a (or 12b) and the intermediate substrate 13 are connected to each other through the bumps 23a (or 23b), each of which has a sufficient size capable of connecting the spacers 12a, 12b and the intermediate substrate 13. Therefore, it becomes possible to suppress a reduced strength of the package substrate 11, a reduced production yield of the semiconductor package 10, a reduced reliability, and the like. In addition, a pitch of the bumps 22a through 23b can be made smaller, which makes it possible to correspond to an increased number of pins.

(1-3) The spacers 12a, 12b are mounted on the upper surface of the package substrate 11. The underfill resin portion 31a (or 31b) fills the space between the package substrate 11 and the spacer 12a (or 12b). The underfill resin portion 31a (or 31b) enhances the connection strength between the package substrate 11 and the spacer 12a (or 12b). With this, the warpage or the like of the package substrate 11 and the spacers 12a, 12b can be suppressed.

Similarly, the end portions of the intermediate substrate 13 are mounted on the upper surfaces of the spacers 12a, 12b, respectively. The underfill resin portion 32a (or 32b) fills the space between the spacer 12a (or 12b) and the intermediate substrate 13. Therefore, the warpage or the like of the spacers 12a, 12b and the intermediate substrate 13 can be suppressed.

(1-4) The spacers 12a, 12b are connected on the upper surface of the package substrate 11. The package substrate 11 extends outwardly from the end portions of the spacers 12a, 12b. Therefore, the underfill resin portion 31a (or 31b) formed between the package substrate 11 and the spacer 12a (or 12b) has the fillet that spreads so as to be smoothly slanted from the lower side portions of the spacer 12a (or 12b) toward the upper surface of the package substrate 11. Therefore, the connection area between the package substrate 11 and the spacers 12a, 12b can be made larger, thereby obtaining a greater connection strength.

Similarly, the spacers 12a, 12b are formed so as to extend outwardly from the end portions of the intermediate substrate 13. The underfill resin portion 32a (or 32b) has the fillet that spreads so as to be smoothly slanted from the lower end surface of the intermediate substrate 13 toward the upper surface of the spacer 12a (or 12b). Therefore, the connection area between the spacers 12a, 12b and the intermediate substrate 13 can be made larger, thereby obtaining a greater connection strength.

### Second Embodiment

In a second embodiment according to the present invention, the same reference symbols are given to the same members described in the previous embodiment, and a part or all of the explanations about these members will be omitted herein.

Referring to FIG. 7, a semiconductor package 40 includes the package substrate 11, two spacerss 41a, 41b, the intermediate substrate 13, the plurality of (six in FIG. 7) semiconductor chips 14a through 14f.

The two spacers 41a, 41b are mounted on the upper surface (the first main surface) of the package substrate 11. The package substrate 11 and the spacer 41a are connected to each other through a plurality of bumps 22a. Similarly, the package substrate and the spacer 41b are connected to each other through a plurality of bumps 22b.

End portions of the intermediate substrate 13 are arranged on the spacers 41a, 41b, respectively. The spacer 41a and the intermediate substrate 13 are connected to each other through a plurality of bumps 23a. Similarly, the spacer 41b and the intermediate substrate 13 are connected to each other through a plurality of bumps 23b. The thicknesses of the semiconductor chips 14e, 14f are, for example, 50 to 700 (micrometer). The thicknesses of the spacers 41a, 41b are, for example, 100 to 800 μm.

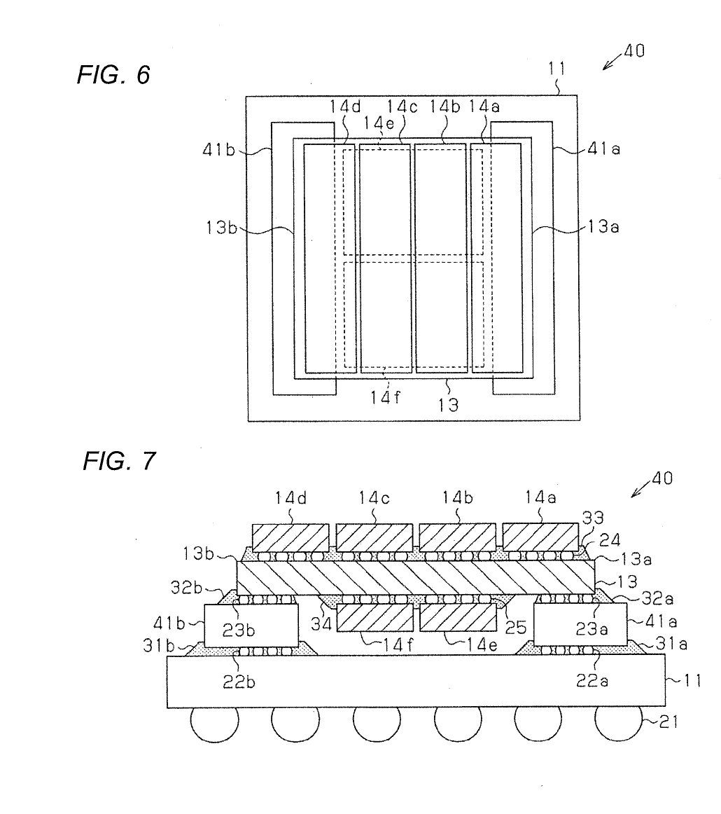

Referring to FIG. 6, the spacerss 41a, 41b have a rectangle planar shape that extends along a pair of opposing sides 13a, 13b of the intermediate substrate 13. The lengths of the spacer 41a, 41b are set to be longer than the sides 13a, 13b of the intermediate substrate 13. In addition, the positions and widths of the spacers 41a, 41b are determined in such a manner that each of the spacers 41a, 41b extends outwardly from the intermediate substrate 13 in a width direction (a horizontal direction in FIG. 6).

Incidentally, referring to FIG. 6, the semiconductor chips 14e, 14f are mounted on the lower surface of the intermediate substrate 13 (see FIG. 7) and arranged in a direction along which the spacers 41a, 41b extend, which is different from those illustrated in FIG. 7. It should be noted that the semiconductor chips 14e, 14f are illustrated in such a different manner in FIG. 7, in order to illustrate two semiconductor chips are mounted on the lower surface of the intermediate substrate 13.

The spacers 41a, 41b are formed of, for example, an organic resin. For example, the spacers 41a, 41b are formed of the same material as that used to form the package substrate 11. The spacers 41a, 41b include one or more wiring layers (not illustrated) that electrically connects the bumps 23a, 23b provided on the first main surfaces (upper surfaces in FIG. 7) of the spacers 41a, 41b and the bumps 22a, 22b provided on the second surfaces (lower surfaces in FIG. 7) of the spacers 41a, 41b, respectively.

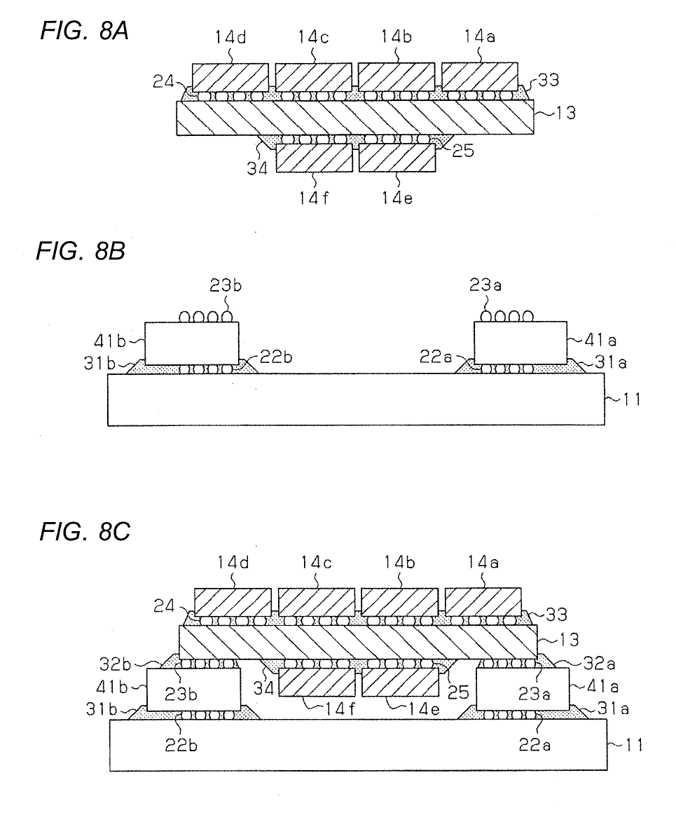

Next, a method of producing the semiconductor package 40 will be explained. Referring to FIG. 8A, the semiconductor chips 14a through 14d are mounted on the upper surface of the intermediate substrate 13; and the semiconductor chips 14e, 14f are mounted on the lower surface of the intermediate substrate 13. Specifically, the semiconductor chips 14a through 14f are adhered on the corresponding surfaces of the intermediate substrate 13, for example, by an adhesive agent or the like, and then connected to the intermediate substrate 13 through the corresponding bumps 24, 25, for example, by performing a re-flow treatment at a temperature of, for example, 250° C. to 270° C. Then, the underfill resin portion 33 is provided between the intermediate substrate 13 and the semiconductor chips 14a through 14d; and the underfill resin portion 34 is provided between the intermediate substrate 13 and the semiconductor chips 14e, 14f. The underfill resin portions 33, 34 are cured at a temperature of, for example, 150° C. to 200° C. by a heating treatment.

Referring to FIG. 8B, the spacers 41a, 41b are mounted on the upper surface of the package substrate 11. Then, underfill resin portion 31a (or 31b) is provided between the package substrate 11 and the spacer 41a (or 41b).

Referring to FIG. 8C, the intermediate substrate 13 is mounted on the upper surfaces of the spacers 41a, 41b. Then, underfill resin portion 32a (or 32b) is provided between the intermediate substrate 13 and the spacer 41a (or 41b).

In a process illustrated in FIG. 8A, the semiconductor chips 14a through 14f and the intermediate substrate 13 are formed of a material using silicon as a base material. Therefore, no warpage is caused by the heating treatment. In addition, in a process illustrated in FIG. 8B, the package substrate 11 and the spacers 41a, 41b are formed of a material using an organic resin as a base material. Therefore, no warpage is caused by the heating treatment.

In a process illustrated in FIG. 8C, the intermediate substrate 13 that is a silicon substrate is mounted on the spacers 41a, 41b formed of an organic base material. At this time, because the coefficient of thermal expansion of the package substrate 11 and the coefficient of thermal expansion of the spacers 41a, 41b or the like are different from each other, warpage is caused by a heating treatment. Regarding such warpage, the two spacers 41a, 41b define a warpage direction along which the package substrate 11 or the like is warped. In addition, the underfill resin portions 31a, 31b enhance stiffness of the package substrate 11 and the spacers 41a, 41b. Similarly, the underfill resin portions 32a, 32b enhance stiffness of the intermediate substrate 13. Therefore, the warpage is reduced.

As is the case with the first embodiment, the spacers 41a, 41b are connected to the intermediate substrate 13 in such a manner illustrated in FIG. 6, which makes it possible to define the warpage direction in the intermediate substrate 13. In addition, the underfill resin portions 31a, 31b can alleviate concentrated stress applied to a region between the package substrate 11 and the spacers 41a, 41b, respectively; and the underfill resin portions 32a, 32b can alleviate concentrated stress applied to a region between the spacers 41a, 41b and the intermediate substrate 13. With this, the connection strength can be effectively suppressed from reducing. In addition, in a case of the spacers 41a, 41b formed of an organic resin, the warpage stress is concentrated to a region between the intermediate substrate 13 and the spacers 41a, 41b. In order to alleviate such warpage stress, it is advantageous to provide the underfill resin portion 32a (or 32b) between the intermediate substrate 13 and the spacer 41a (or 41b), respectively.

As described above, the same effect as the effects obtained by the first embodiment can be obtained by the semiconductor package 40 according to the second embodiment, which includes the spacers 41a, 41b of the organic substrate.

### Third Embodiment

In a third embodiment according to the present invention, the same reference symbols are given to the same members described in the previous embodiments, and a part or all of the explanations about these members will be omitted herein.

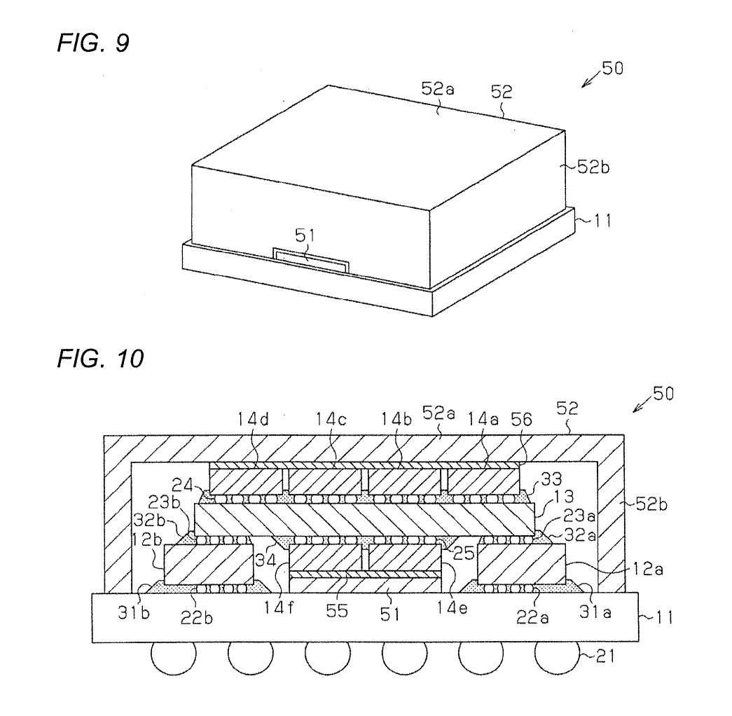

Referring to FIG. 9, a semiconductor package 50 includes the package substrate 11, and a heat sink 51 and a heat dissipating cover 52 that are connected to the upper surface of the package substrate 11.

Referring to FIG. 10, the package substrate 11, the two spacers 12a, 12b, the intermediate substrate 13, six semiconductor chips 12a through 12f are arranged inside the heat dissipating cover 52. The heat sink 51 is arranged between the upper surface of the package substrate 11 and the lower surfaces of the semiconductor chips 14e, 14f mounted on the lower surface of the intermediate substrate 13.

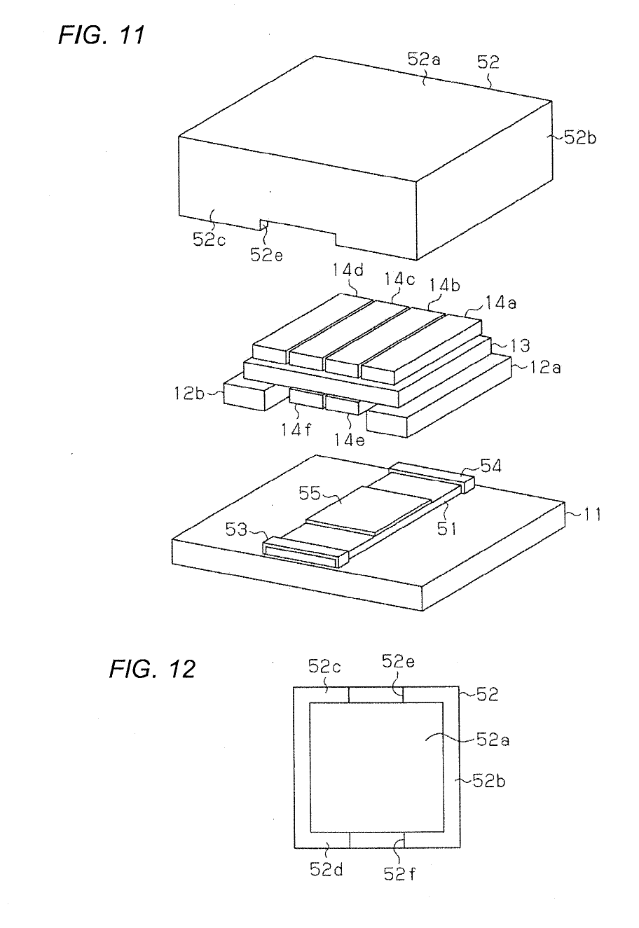

Referring to FIG. 11, the heat sink 51 has a shape of a rectangular plate. The heat sink 51 is connected to the upper surface of the package substrate 11 through a bonding member (not illustrated). The heat sink 51 is one example of a first heat dissipating member. The heat dissipating cover 52 is formed of, for example, copper (Cu), aluminum (Al), an alloy of these metals, or the like.

Referring again to FIG. 10, the thickness of the heat sink 51 is determined depending on a distance from the package substrate 11 to the lower surfaces of the semiconductor chips 14e, 14. In addition, the width of the heat sink 51 (the left-and-right length in FIG. 10) is made narrower than a space between the two spacers 12a, 12b.

Referring back to FIG. 11, thermal interface materials (TIMs) 53, 54 are provided on the upper surface and the side surfaces of respective end portions of the heat sink 51. In addition, a thermal interface material 55 is provided in a center region on the upper surface of the heat sink 51. The thermal interface materials 53, 54, 55 are formed of, for example, an organic resin binder or the like that has a low coefficient of elasticity and contains a filler of a metal such as silver, copper, and nickel, or an inorganic material having a greater thermal conductive coefficient than that of an organic material, such as silica, alumina, boron nitride, or the like.

Referring again to FIG. 9, the thermal interface material 53 is provided between the heat sink 51 and the heat dissipating cover 52. Incidentally, although not illustrated in FIG. 9, the thermal interface material 54 is also provided between the heat sink 51 and the heat dissipating cover 52 (see FIG. 11). The thermal interface materials 53, 54 thermally connect the heat sink 51 and the heat dissipating cover 52.

Referring again to FIG. 10, the thermal interface material 55 is provided between the heat sink 51 and the semiconductor chips 14e, 14f. The thermal interface material 55 thermally connects the heat sink 51 and the semiconductor chips 14e, 14f.

As illustrated in FIG. 10, the heat dissipating cover 52 includes a plate member 52a having the shape of a plate, and a side wall portion 52b. The top end of the side wall portion 52b is integrally connected with a periphery of the plate member 52a; and the bottom end of the side wall portion 52b is connected on the package substrate 11 through a bonding member (not illustrated). The heat dissipating cover 52 is one example of a second heat dissipating portion. The heat dissipating cover 52 is formed of, for example, copper (Cu), aluminum (Al), an alloy of these metals, or the like. The heat dissipating cover 52 configured as above may be formed by, for example, a forge processing method, a machining method, or the like.

Referring to FIG. 12, the side wall portion 52b has the shape of a rectangle frame in planar view. Connecting portions 52e, 52f are provided in central lower end portions of a pair of a side wall 52c and a side wall 52d, which oppose to each other, of the side wall portion 52b, respectively. As illustrated in FIG. 11, the connecting portion 52e is formed so as to be recessed from the lower end of the side wall 52c toward the plate portion 52a. The connecting portion 52e allows the inside and the outside of the side wall portion 52b to be communicated with each other. Incidentally, although not illustrated in FIG. 11, the connecting portion 52f is formed in the same manner as the connecting portion 52e.

The Sizes of the connection portions 52e, 52f are determined depending on the size of the heat sink 51. The widths of the connecting portions 52e, 52f are greater than the width of the heat sink 51. Specifically, the connecting portions 52e, 52f are formed so that the thermal interface materials 53, 54 can be provided between inner surfaces of the connecting portions 52e, 52f and upper and side surfaces of the heat sink 51. More specifically, the connecting portions 52e, 52f are formed so that the thermal interface materials 53, 54 are attached firmly on the inner surface of the connection portions 52e, 52f and the upper and side surfaces of the heat sink 51. The length of the heat sink 51 is set to be substantially equal to the length of the side of the heat dissipating cover 52, the side extending in a direction perpendicular to the sides walls 52c, 52c where the connection portions 52e, 52f are formed, respectively, (or a side that extends in an upward-and-downward direction in FIG. 12). With this, the heat sink 51 is thermally connected to the side wall portion 52b of the heat dissipating cover 52 through the thermal interface materials 53, 54.

Referring to FIG. 10, a thermal interface material 56 is provided between the upper surfaces of the semiconductor chips 14a through 14d and the lower surface of the plate portion 52a. The semiconductor chips 14a through 14d are thermally connected to the plate portion 52a of the heat dissipating cover 52 through the thermal interface material 56.

Effects obtained by the semiconductor package 50 will be explained.

As illustrated in FIG. 10, the semiconductor chips 14a through 14d are mounted on the upper surface of the intermediate substrate 13 and thermally connected to the heat dissipating cover 52 through the thermal interface material 56. Therefore, heat generated in the semiconductor chips 14a through 14d is transmitted to the heat dissipating cover 52 through the thermal interface material 56, and dissipated from the heat dissipating cover 52 to the atmosphere. Thus, the heat generated from the semiconductor chips 14a through 14d can be efficiently dissipated, thereby to suppress the rise in temperatures of the semiconductor chips 14a through 14d.

In addition, the semiconductor chips 14e, 14f are mounted on the lower surface of the intermediate substrate 13 and thermally connected to the heat sink 51 arranged underneath the semiconductor chips 14e, 14f through the thermal interface material 55. Therefore, heat generated from the semiconductor chips 14e, 14f is transmitted to the heat sink 51 through the thermal interface material 55. The heat sink 51 is thermally connected at both ends thereof to the side wall portion 52b of the heat dissipating cover 52 through the thermal interface materials 53, 54.

Therefore, the heat generated from the semiconductor chips 14e, 14f is transmitted to the heat sink 51 through the thermal interface material 55, and further to the heat dissipating cover 52 through the thermal interface materials 53, 54. Finally, the heat is dissipated from the heat dissipating cover 52to the atmosphere.

The heat generated from the semiconductor chips 14e, 14f can be efficiently dissipated, thereby to suppress the rise in temperatures of the semiconductor chips 14e, 14f. In addition, the heat generated from the semiconductor chips 14e, 14f mounted on the lower surface of the intermediate substrate 13 is suppressed from being transmitted to the semiconductor chips 14a through 14d mounted on the upper surface of the intermediate substrate 13.

As described above, the advantages obtained by this embodiment are substantially summarized as follows.

(3-1) The heat sink 51 is provided between the package substrate 11 and the semiconductor chips 14e, 14f mounted on the lower surface of the intermediate substrate 13, and connected to the semiconductor chips 14e, 14f through the thermal interface material 55. Therefore, the semiconductor chips 14e, 14f are thermally connected to the heat sink 51 through the thermal interface material 55, thereby to efficiently dissipate the heat of the semiconductor chips 14e, 14f.

(3-2) The end portions of the heat sink 51 is made protruded from the end portions of the intermediate substrate 13 in planar view, and thermally connected to the heat dissipating cover 52 through the thermal interface materials 53, 54. Therefore, the heat of the semiconductor chips 14e, 14f can be efficiently dissipated.

Incidentally, the above embodiments may be modified as follows.

The heat generated from the semiconductor chips 14e, 14f mounted on the lower surface of the intermediate substrate 13 may be dissipated, for example, to the package substrate 11. In this case, an adhesive sheet or an underfill resin that have relatively greater heat conductivity may be used, as explained below.

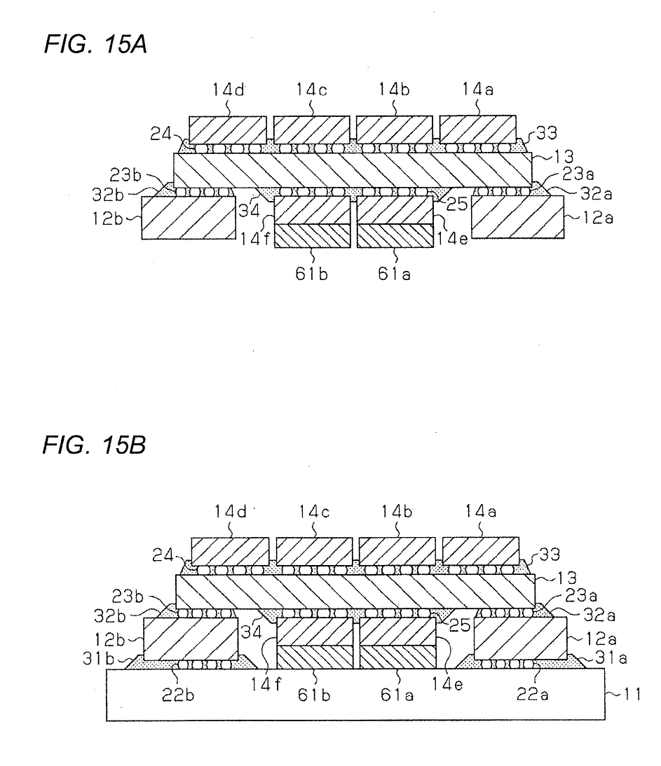

Referring to FIG. 15A, the intermediate substrate 13 having the semiconductor chips 14a through 14f mounted thereon is mounted on the spacers 12a, 12b. Then, adhesive sheets 61a, 61b are adhered on the lower surfaces of the semiconductor chips 14e, 14f, respectively. Next, as illustrated in FIG. 15B, the adhesive sheets 61a, 61b are affixed on the upper surface of the package substrate 11. The adhesive sheets 61a, 61b are more heat-conductive than air existing in a gap between the upper surface of the package substrate 11 and the lower surfaces of the semiconductor chips 14e, 14f. Therefore, the heat generated from the semiconductor chips 14e, 14f is efficiently transmitted to the package substrate 11, and thus heat dissipation can be improved, as compared with the use of the air gap. The adhesive sheets 61a, 61b are one example of the thermal interface material.

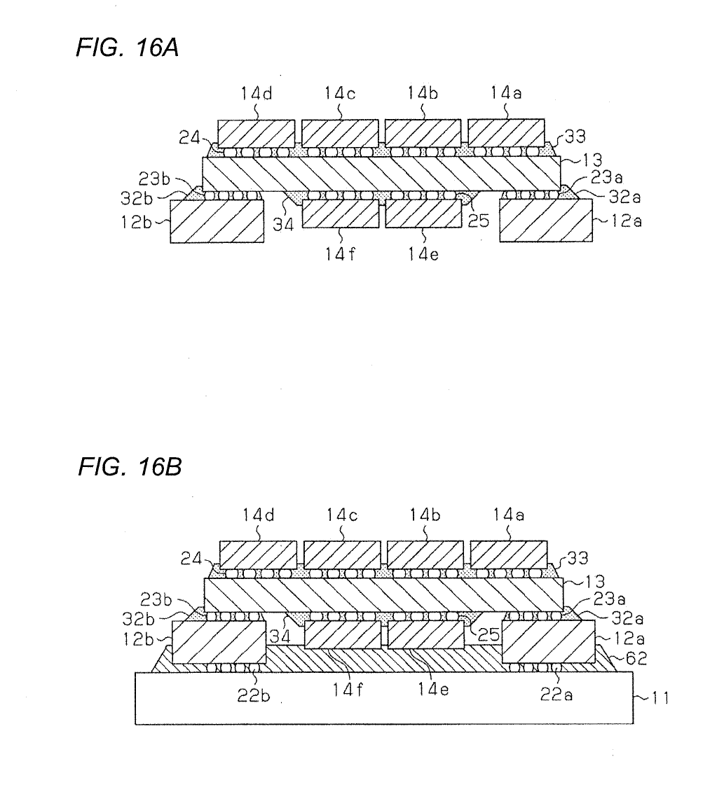

Alternatively, as illustrated in FIG. 16A, the intermediate substrate 13 having the semiconductor chips 14a through 14f mounted thereon is mounted on the spacers 12a, 12b. Next, the spacers 12a, 12b are mounted on the package substrate 11. Then, a resin material is injected into spaces between the package substrate 11 and the spacers 12a, 12b, and between the package substrate 11 and the semiconductor chips 14e, 14f, and then cured. Thus, an underfill resin portion 62 is provided, as illustrated in FIG. 16B. The underfill resin portion 62 is more heat-conductive than air existing in a gap between the upper surface of the package substrate 11 and the lower surfaces of the semiconductor chips 14e, 14f. Therefore, the heat generated from the semiconductor chips 14e, 14f is efficiently transmitted to the package substrate 11, and thus heat dissipation can be improved, as compared with use of the air gap. The underfill resin portion 62 is one example of the thermal interface material.

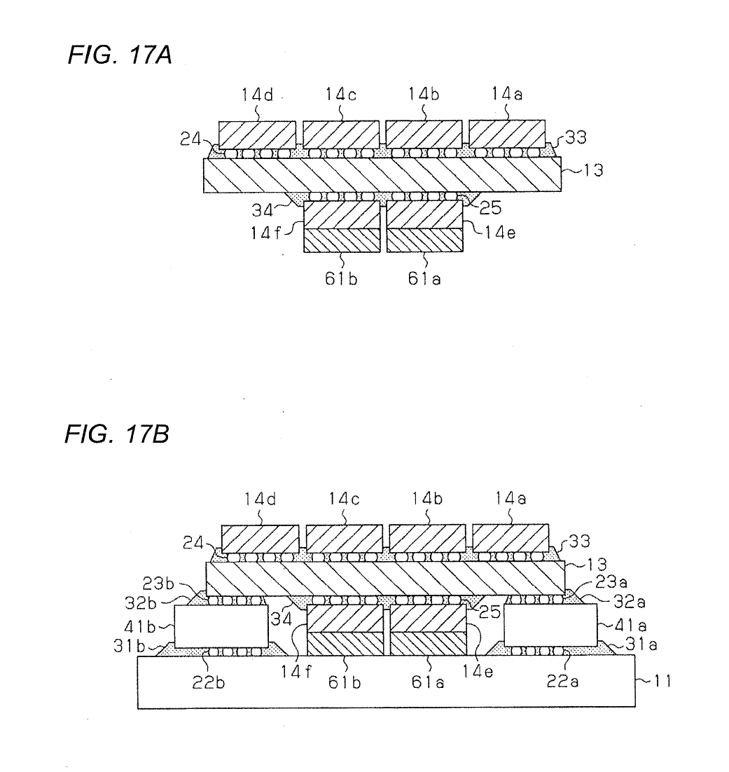

Alternatively, as illustrated in FIG. 17A, the semiconductor chips 14a through 14f are mounted on the intermediate substrate 13, and then the adhesive sheets 61a, 61b are affixed on the lower surfaces of the semiconductor chips 14e, 14f, respectively. Next, as illustrated in FIG. 17B, the intermediate substrate 13 is mounted on the spacers 41a, 41b mounted on the package substrate 11. At this time, the adhesive sheets 61a, 61b are adhered on the upper surface of the package substrate 11. The adhesive sheets 61a, 61b are more heat-conductive than air existing in a gap between the upper surface of the package substrate 11 and the lower surfaces of the semiconductor chips 14e, 14f. Therefore, the heat generated from the semiconductor chips 14e, 14f is efficiently transmitted to the package substrate 11, and thus heat dissipation can be improved, as compared with use of the air gap.

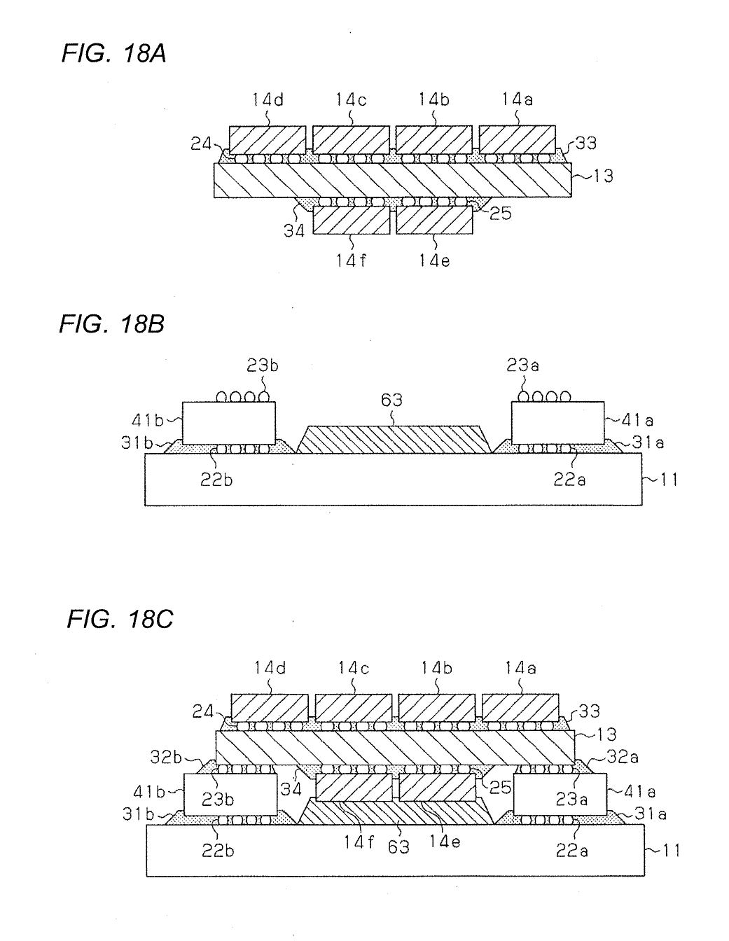

Alternatively, as illustrated in FIG. 18A, the semiconductor chips 14a through 14f are mounted on the intermediate substrate 13. On the other hand, the spacers 41a, 41b are mounted on the package substrate 11, and an underfill resin portion 31a (or 31b) are provided between the package substrate 11 and the spacer 41a (or 41b), as illustrated in FIG. 18B. Then, an adhesive sheet 63 is affixed on a predetermined portion (or an area where the semiconductor chips 14e, 14f are to be arranged) of the upper surface of the package substrate 11. Next, as illustrated in FIG. 18C, the intermediate substrate 13 is mounted on the spacers 41a, 41b. At this time, the lower surfaces of the semiconductor chips 14e, 14f mounted on the lower surface of the intermediate substrate 13 is adhered on the package substrate 11 through the adhesive sheet 63. The adhesive sheet 63 is more heat-conductive than air existing in a gap between the upper surface of the package substrate 11 and the lower surfaces of the semiconductor chips 14e, 14f. Therefore, the heat generated from the semiconductor chips 14e, 14f is efficiently transmitted to the package substrate 11, and thus heat dissipation can be improved, as compared with the use of the air gap. The adhesive sheet 63 is one example of the thermal interface material.

Incidentally, in the semiconductor package 10 having the spacers 12a, 12b that are silicon substrates, heat may be dissipated from the semiconductor chips 14e, 14f to the package substrate 11 by using the adhesive sheet 63 illustrated in FIG. 18B.

Other examples of modifications will be explained as follows. The heat sink 51 and the heat dissipating cover 52 of the third embodiment may be applied to the semiconductor package 40 having the spacers 41a, 41b of the organic substrate according to the second embodiment.

In each of the above embodiments, a shape of the semiconductor chips or the number of the semiconductor chips that are mounted on the intermediate substrate 13 may be arbitrarily changed.

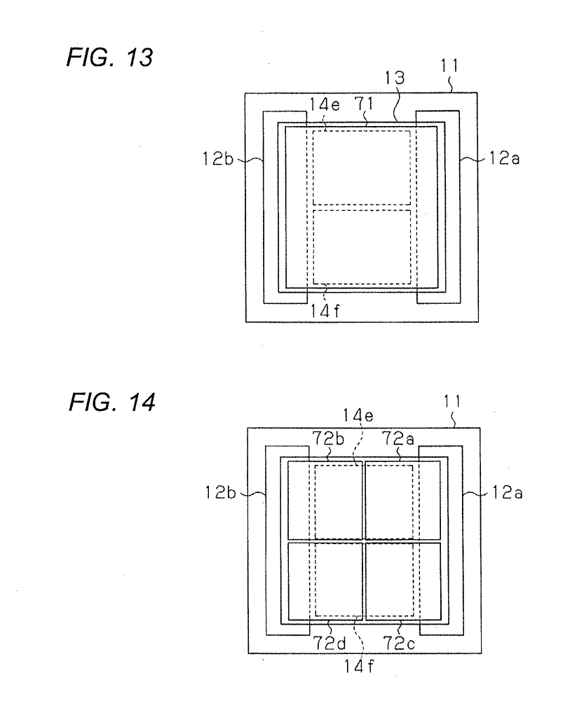

In addition, as illustrated in FIG. 13, one semiconductor chip 71 may be mounted on the upper surface of the intermediate substrate 13, for example. Moreover, as illustrated in FIG. 14, four semiconductor chips 72a through 72d may be arranged in a matrix on the upper surface of the intermediate substrate 13.

Incidentally, the two semiconductor chips 14e, 14f are mounted on the lower surface of the intermediate substrate 13 in each of the above embodiments and modified examples of FIGS. 13 and 14. However, one or three or more semiconductor chip(s) may be mounted on the lower surface of the intermediate substrate 13.

The shapes of the semiconductor chips 14e, 14f mounted on the lower surface of the intermediate substrate 13 in FIGS. 1 and 6 may be the same as those of the semiconductor ships 14a through 14d.

In each of the above embodiments and modifications, one intermediate substrate 13 is mounted on the package substrate 11. However, a plurality of intermediate substrates may be mounted on the package substrate 11.

The semiconductor chips 14 may be provided so as to stride over a region where the intermediate substrate 13 and the spacers 12a, 12b are overlapped in planar view.

When the intermediate substrate 13 is an extremely thin substrate, there may be a concern that a portion of the intermediate substrate 13, excluding portions where the intermediate substrate 13 is connected to the spacers 12a, 12b, is warped by the weight of the semiconductor chips 14 or the intermediate substrate 13. Such warpage of the intermediate substrate 13 can be reduced by arranging the semiconductor chips 14e, 14f on the lower surface of the intermediate substrate 13 in such a manner that long sides of the semiconductor chips 14e, 14f extend in a direction perpendicular to the direction along which the spacers 12a, 12b extend on the lower surface of the intermediate substrate 13. For example, it is advantageous to arrange the semiconductor chips 14e, 14f as illustrated in FIG. 1.

When a plurality of semiconductor chips are mounted on the first main surface of the intermediate substrate 13, it is effective, in order to reduce warpage of the intermediate substrate 13, to arrange the semiconductor chips on the second main surface of the intermediate substrate 13 in positions corresponding to spaces between the plurality of semiconductor chips mounted on the first main surface.

The third embodiment may be modified as follows. One end of the heat sink 51 is made protruded from an end portion of the intermediate substrate 13 along the package substrate 11, and the protruded portion of the heat sink 51 may be electrically connected to the heat dissipating cover 52 through a thermal interface material.

The heat dissipating cover 52 in the third embodiment may be omitted.

The heat dissipating cover 52 in the third embodiment may be formed of a plurality of members.

The heat sink 51 in the third embodiment may be formed of a plurality of heat sinks.

As described above, the preferred embodiment and the modifications are described in detail. However, the present invention is not limited to the above-described embodiment and the modifications, and various modifications and replacements are applied to the above-described embodiment and the modifications without departing from the scope of claims.

What is claimed is:

1. A semiconductor package comprising:
a first wiring substrate;
a first spacer on the first wiring substrate, wherein the first spacer has a rectangular shape having opposed short sides and opposed long sides;
a second spacer on the first wiring substrate to be separated from the first spacer, wherein the second spacer has a rectangular shape having opposed short sides and opposed long sides;
a second wiring substrate on the first spacer and the second spacer and comprising a first surface and a second surface which is opposite to the first surface and faces the first and second spacers, wherein the second wiring substrate has opposed sides;
a first semiconductor chip on the first surface of the second wiring substrate; and
a second semiconductor chip on the second surface of the second wiring substrate to be disposed between the first spacer and the second spacer, and
wherein the opposed long sides of the first spacer and the opposed long sides of the second spacer are substantially parallel with the opposed sides of the second wiring substrate.

2. The semiconductor package according to claim 1, wherein the first spacer is disposed to extend outwardly from corresponding one of the opposed sides of the second wiring substrate when viewed from a top,
the second spacer is disposed to extend outwardly from the other side of the second wiring substrate when viewed from the top, and
an underfill resin is provided between the second wiring substrate and the first spacer and between the second wiring substrate and the second spacer.

3. The semiconductor package according to claim 1, wherein
the first semiconductor chip comprises a plurality of first semiconductor chips, each of which has a rectangular shape having opposed short sides and opposed long sides, and
the opposed long sides of each of the plurality of first semiconductor chips are substantially parallel with the opposed sides of the second wiring substrate.

4. The semiconductor package according to claim 3, wherein
the second semiconductor chip is disposed on the second surface of the second wiring substrate to be overlapped with a space between adjacent ones of the first semiconductor chips when viewed from the top.

5. The semiconductor package according to claim 3, wherein
the second semiconductor chip has a rectangular shape having opposed short sides and opposed long sides, and
the opposed long sides of the second semiconductor chip are substantially perpendicular to the opposed sides of the second wiring substrate.

6. The semiconductor package according to claim 1, further comprising:
a first heat dissipating member disposed between the first wiring substrate and the second semiconductor chip and thermally connected to the second semiconductor chip.

7. The semiconductor package according to claim 6,
wherein the first heat dissipating member has a rectangular plate shape, and
wherein at least one of both end portions of the first heat dissipating member extends outwardly from an end portion of the second wiring substrate when viewed from the top, and
the semiconductor package further comprising:
a second heat dissipating member thermally connected to the extended end portion of the first heat dissipating member.

8. The semiconductor package according to claim 7,
wherein the second heat dissipating member is thermally connected to the first wiring substrate and covers the first semiconductor chip, and
wherein the first semiconductor chip is thermally connected to the second heat dissipating member.

9. The semiconductor package according to claim 6,
wherein the first heat dissipating member is configured to transmit heat generated from the first and second semiconductor chips to the first wiring substrate.
